(19) United States
(12) Patent Application Publication
(10) Pub. No.: US 2007/0075218 A1
(43) Pub. Date: Apr. 5, 2007

(54) Multiple exposure optical imaging apparatus

(76) Inventors: John VanAtta Gates, New Providence, NJ (US); Carl Jeremy Nuzman, Union, NJ (US); Stanley Pau, Tucson, AZ (US)

Correspondence Address: Michael J. Urbano, 1445 Princeton Drive, Bethlehem, PA, 18017-9166, US

(21) Appl. No.: 11/242,751

(22) Filed: Oct. 4, 2005

(51) Int. Cl. H01L 27/00

(52) U.S. Cl. 250/208.1

(57) ABSTRACT

Apparatus for storing an optical image of an object comprises an imaging device having a multiplicity of pixels, each pixel including a light sensor and a multiplicity of storage cells coupled to the sensor. A lens system focuses light from the object onto the imaging device. Within each pixel a first one of its storage cells is configured to store data corresponding to a first exposure of its sensor to light from the object, and a second one of its storage cells is configured to store data corresponding to a second exposure of its sensor to light from the object. In a preferred embodiment, the pixels are arranged in an array extending along a first direction, and during the time interval between the first and second exposures, a translator is configured to produce, in a second direction, a relative translation or shift between the imaging device and the focal point of the lens system. In one embodiment, the second direction is traverse to the first direction. In a preferred embodiment, each pixel comprises a photosensitive region, and the pixels are shifted by a distance that is approximately equal to one half the pitch of the photosensitive regions as measured in the second direction. In this fashion, the invention increases the spatial resolution by increasing the effective number of pixels of the sensor without increasing the actual number of pixels. In alternative embodiment of the invention, the dynamic range of the sensor is enhanced.

### BACKGROUND OF THE INVENTION

1. Field of the Invention

This invention relates to apparatus for storing optical images in electronic form and, more particularly, to digital cameras for storing either still images, video images, or both.

2. Discussion of the Related Art

The trend in the development of digital cameras is to increase spatial resolution by increasing the number of pixels in the camera's image converter. The converter is a form of light detection sensor, typically a charge coupled device (CCD) or complementary metal oxide semiconductor (CMOS) device. For a given size light sensor [e.g., the 24 mm×36 mm sensor area of a standard single lens reflex (SLR) camera], increasing the number of pixels implies reducing the size of each pixel. However, smaller pixels collect fewer photons, which decreases the camera's signal-to-noise ratio. It is known that this problem can be alleviated in several ways: by using a micro-lens array to increase light collection efficiency, by improving the design and fabrication of the pixels so as to reduce noise, and/or by employing a signal processing algorithm to extract real time signals from noisy data.

Nevertheless, the state of the art light sensor is still limited by both the shot noise in the collected photons and the electronic noise of the converter circuits. The shot noise of light is fundamental and cannot be reduced, whereas the electronic noise can be reduced by cooling the sensor, albeit at the expense of increased power consumption. Thus, there is a practical limit to the number of pixels that can be put in the typical area of a SLR camera.

The current digital SLR camera with the highest resolution (16.7 megapixels) is the EOS 1Ds Mark II camera manufactured by Canon. The resolution of this camera is comparable to ISO 100 film of the same size and surpasses that of many ISO 400 films. One can argue that a sensor with a higher density of pixels than that of the Canon EOS 1Ds Mach II is currently unnecessary, but the need for higher resolution seems to march on inexorably—there always seem to be photographers who seek a camera with higher megapixel density and higher sensitivity. (Note, higher pixel counts exist in medium frame format cameras, but higher densities do not.) Thus, there is a need in the digital camera art for a higher spatial resolution digital camera that does not suffer from the increased noise problem that would be attendant the use of smaller size pixels.

In addition, in some digital cameras the light sensors contain what is known in the art as dead space, portions of the sensor surface area that are either insensitive to light or shielded from light. By decreasing the fraction of sensor surface area that is photosensitive, dead space also decreases spatial resolution. Various light sensor designs give rise to dead space; for example, in one design, each pixel may comprise a photocell and dead space formed by a laterally adjacent storage cell (or readout cell); in another design, the sensor may comprise photocells that are responsive to different wavelengths of light (e.g., primary colors), wherein, for example, blue and green photocells are considered dead space relative to red photocells; and in yet another design, the sensor may comprise photocells that are responsive to different intensities of light, wherein, for example, photocells that are sensitive to lower intensities are considered dead space relative to photocells that are sensitive to higher intensities.

Regardless of the type of dead space that is designed into a digital camera's light sensor, there is also a need in the art to increase the spatial resolution of such cameras.

### BRIEF SUMMARY OF THE INVENTION

In accordance with one aspect of our invention, apparatus for storing an optical image of an object comprises an imaging device having a multiplicity of pixels, each pixel including a light sensor and a multiplicity of storage cells coupled to the sensor. A lens system focuses light from the object onto the imaging device. Within each pixel a first one of its storage cells is configured to store data corresponding to a first exposure of its sensor to light from the object, and a second one of its storage cells is configured to store data corresponding to a second exposure of its sensor to light from the object. In a preferred embodiment, the pixels are arranged in an array extending along a first direction, and during the time interval between the first and second exposures, a translator is configured to produce, in a second direction, a relative translation or shift between the imaging device and the focal point of the lens system. In one embodiment, the second direction is traverse to the first direction. In a preferred embodiment, each pixel comprises a photosensitive region, and the pixels are shifted by a distance that is approximately equal to one half the pitch of the photosensitive regions as measured in the second direction.

In this fashion, we increase spatial resolution by increasing the effective number of pixels of the sensor without increasing the actual number of pixels. Thus, a sensor with only N pixels has the effective resolution of a sensor having 2N pixels.

In accordance with another aspect of our invention, a method of generating electronic data representing an optical image of an object comprises the steps of: (a) making light emanating from the object incident upon the pixels of an optical imaging device; (b) providing multiple exposures of the pixels during step (a), each exposure generating electronic image data within the pixels; and (c) after each exposure transferring the data into a subset of readout devices, different subsets receiving data during consecutive transfer operations.

Thus, an increase in spatial resolution is achieved by multiple exposures and readouts of the image data at different spatial locations of the sensor.

In yet another embodiment of our invention, dynamic range is increased without the need to translate the imaging device between the first and second exposures. In this case, however, these exposures have different durations.

### BRIEF DESCRIPTION OF THE SEVERAL VIEWS OF THE DRAWING

Our invention, together with its various features and advantages, can be readily understood from the following more detailed description taken in conjunction with the accompanying drawing, in which:

FIG. 1 is a block diagram of a digital camera in accordance with one embodiment of our invention;

FIG. 2 is a schematic, top view of CCD pixels in accordance with one embodiment of our invention;

FIG. 3 is a schematic, top view of illustrative apparatus for shifting the imaging device of FIG. 1 and hence the pixels of FIG. 2 or FIG. 6;

FIGS. 4 & 5 are schematic, top views of pixels showing how they are shifted in accordance with alternative embodiments of our invention; and

FIG. 6 is a schematic, top view of CCD pixels in accordance with an alternative embodiment of our invention.

### DETAILED DESCRIPTION OF THE INVENTION

Digital Camera Configuration

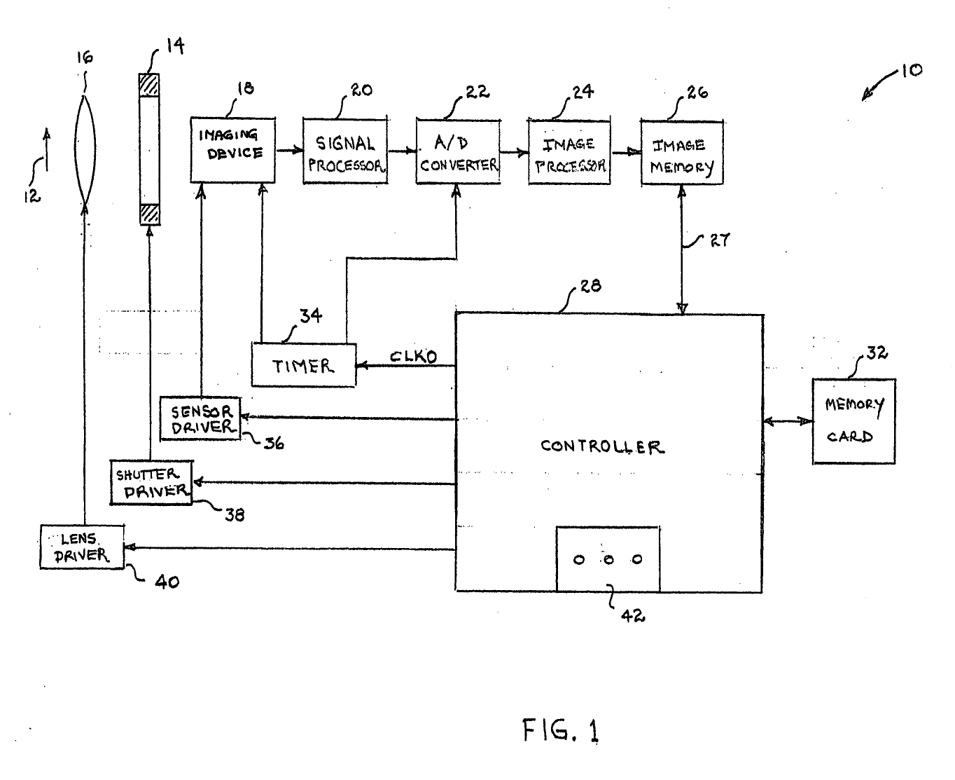

Before discussing our invention in detail, we turn first to FIG. 1, which shows a block diagram of a well-known optical imaging apparatus 10 for generating and storing or recording electronic data representing an optical image of an object 12. (By the term object we mean anything from which light emanates by a process of, for example, reflection, refraction, scattering, or internal generation.) For simplicity we will assume in the following discussion that apparatus 10 is a digital camera comprising a shutter 14 for alternately blocking light from image 12 from entering the camera or transmitting such light into the camera. Such digital cameras are well known to have the capability of generating still images, video images, or both.

When the shutter 14 is open, light from object 12 is focused by a lens system 16 onto an imaging device 18. The lens system typically includes a zoom lens subsystem, a focusing lens subsystem and/or an image shift correcting subsystem (none of which are shown in FIG. 1). The imaging device 18 illustratively comprises a well-known CCD or CMOS device, but we will assume, again for simplicity, that imaging device 18 is a CCD in the following discussion. The CCD is typically a color area sensor comprising an array of pixels arranged in rows and columns, with the separate pixels configured to receive red, blue and green color components. As is well known in the art, during an exposure operation, the pixels photoelectrically convert light from image 12 into electronic data in the form of analog image signals corresponding to the intensity of the color components. Subsequently, the data is transferred out of the pixels. The exposure and transfer operations are alternated in a predetermined cycle, typically on the order of 15 ms.

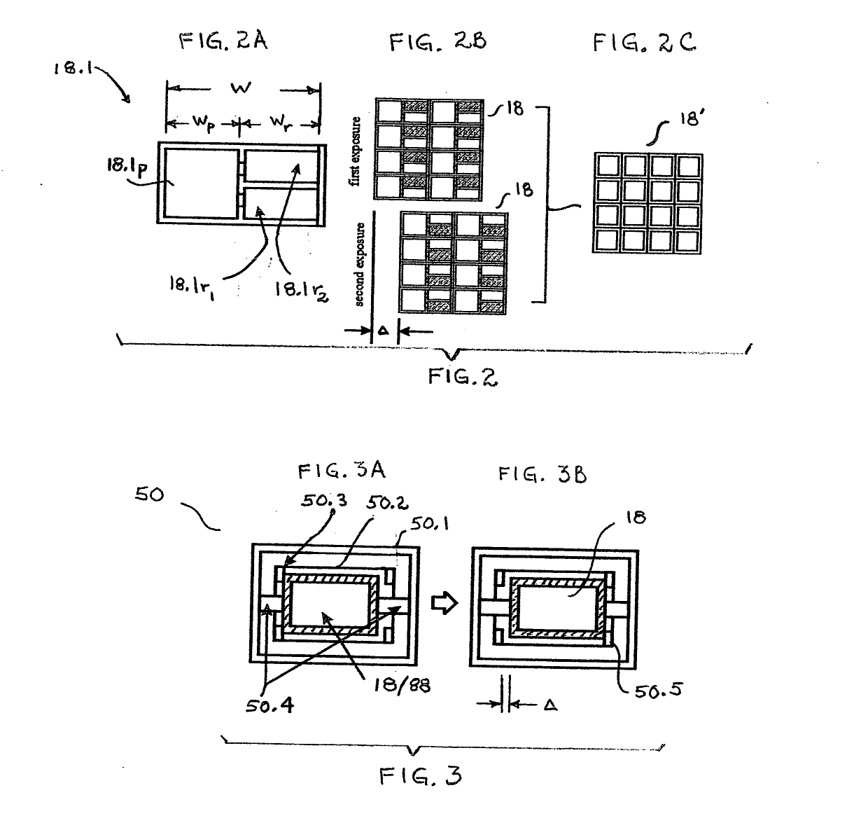

In an illustrative embodiment of our invention, CCD 18 has an interline (IL) architecture of the type described in an article published by Eastman Kodak Co., Microelectronics Technology Division, Rochester, N.Y., entitled “Charge-Coupled Device (CCD) Image Sensor,” Kodak CCD Primer, Document #KCP-001 (2001), which is incorporated herein by reference. This article can be found at internet websites having the following URLs: http://www.kodak.com/US/en/digital/pdf/ccdPrimerPart2.pdf. or http://www.extremetech.com. The IL architecture separates the photo-detecting and readout functions by forming isolated photosensitive regions in between lines of non-sensitive or light-shielded parallel readout CCDs. Our CCD is modified, however, to process multiple exposures, as described below in conjunction with FIGS. 2-6.

The image signals generated by CCD 18 are coupled to a signal processor 20, typically a digital signal processor (DSP). Illustratively, processor 20 reduces the noise in the images signals from the CCD 18 and adjusts the level (amplitude) of the image signals.

The output of signal processor 20 is coupled to an analog-to-digital (A/D) converter 22, which converts the processed analog image signals to digital signals having a predetermined bit length (e.g., 12 bits) based on a clock signal provided by timer 34. In many applications, the signal processor 20 and the A/D converter 22 are integrated in a single chip.

These digital image signals are provided as inputs to an image processor 24, which typically performs a variety of operations including, for example: (i) black level correction; i.e., correcting the black level of the digital signals generated by A/D converter 22 to a reference black level; (ii) white balance correction; i.e., performing level conversion of the digital signals of each color component from A/D converter 22; and (iii) gamma correction; i.e., correcting the gamma characteristics of the digital signals from A/D converter 22.

Image memory 26, which is coupled to controller 28 via bidirectional bus 27, temporarily stores the processed digital signals from image processor 24 in the photographing mode and temporarily stores image data read out of memory card 32 in the playback mode.

Memory card 32 is coupled to controller 28 via a standard I/F interface (not shown) for writing image data into and reading image data from the card 32.

The controller 28 is typically a microcomputer, which includes memory (not shown) (e.g., RAM for storing image signals transferred from image memory 26 and ROM for storing programs for various camera functions); a timing generator (not shown) of clock signal CLK0, and a servo generator (not shown) of controls signals for controlling the physical movement of light sensor 18, lens system 16 and shutter 14 via, respectively, sensor driver 36, lens driver 38 and shutter driver 40. Importantly, controller 28 generates control signals for shifting the lateral position of light sensor 18 relative to the focal point of lens system 16 via sensor driver 36. The latter operation will be described in greater detail in the next section.

External inputs to the controller are typically generated by means of control pad 42. These inputs might include, for example, a shutter button, a mode setting switch, and an image shift correction on/off switch.

Enhanced Effective Spatial Resolution Embodiments: Readout Regions as Dead Space

In FIG. 2 we show an imaging device 18 in accordance with one embodiment of our invention. Imaging device 18 is depicted as a CCD having an array of N pixels 18.1 arranged, for example, in an IL architecture of the type discussed above, but modified as follows to process multiple exposures and to increase the apparent spatial resolution of the camera. The shape of each pixel 18.1 is essentially rectangular having a width w as shown in FIG. 2A, although other geometric shapes are feasible. Each pixel comprises a photosensitive region (or light sensor) 18.1p of width wₚ and a multiplicity of n readout regions (or storage cells) 18.1r each of width wᵣ. Typically, w˜wₚ+wᵣ. The readout regions 18.1r are electronically coupled to their corresponding photosensitive region 18.1p and are designed either to be insensitive to light emanating from object 12 or to be shielded from that light. Since the readout regions do not contribute to the conversion of light to electricity (i.e., charge), they constitute dead space. Additional dead space typically found in an imaging device includes, for example, the area occupied by wiring, storage capacitors, and logic circuits.

Preferably the surface area occupied by the dead space of each pixel should not be less than about (n−1)/n of the total pixel area; e.g., for n=2, as in FIG. 2, the area occupied by the readout regions should be at least about one half of the total pixel area; for n=3, the area occupied by the readout regions should be at least about two thirds of the total pixel area. On the other, under certain circumstances the fraction of the surface area of each pixel occupied by dead space may be less than (n−1)/n, say (n−m)/n, where 1<m<2. As long as the parameter m is not too close to two, then the post-processing described infra in conjunction with FIG. 5 can be utilized to insure enhanced spatial resolution.

The readout regions 18.1r may be located on the same side of the photosensitive region 18.1p, as depicted in FIG. 2A, or on different sides of the pixel. The latter configuration is shown in the light sensor 88 of FIG. 6 where the readout regions 88.1r are located on opposite sides of photosensitive region 88.1p. Other configurations, although somewhat more complex, can readily be visualized by those skilled in the art (e.g., one readout region located along one or more of the side edges of each photosensitive region and one or more readout regions located along its top and/or bottom edges.) In addition, although FIGS. 2 and 6 depict the photosensitive regions as if they were positioned on essentially the same plane, it also possible for them to located on different planes of a multilayered imaging device structure. For example, locating the readout regions under the photosensitive regions would increase the fraction of the device surface area that is photosensitive, but at the expense of more complicated processing.

For purposes of simplicity and ease of illustration only, we have chosen N=8 (two columns each having four pixels, as shown in FIGS. 2B and 6) and n=2 [each photosensitive region 18.1p (88.1p ) coupled to two readout regions 18.1r (88.1r), as shown in FIGS. 2A and 6], with the understanding that those skilled in the art will appreciate that N is typically much larger than eight (e.g., of the order of 10⁶) and n may be somewhat larger than 2 (but with attendant increase in complexity).

The CCD 18 (88) is configured to change its lateral position by an amount Δ with respect to the focal point of lens system 16 during the time period that the shutter remains open and, therefore, light from object 12 falls upon the CCD. By lateral position we mean that the CCD is typically moved in a direction transverse to the columns of the CCD. Thus, the direction of the movement may be perpendicular to the direction of the columns (FIG. 2B) or oblique thereto (not shown). Preferably the pixels are shifted by a distance Δ that is approximately equal to one half the pitch of the photosensitive regions in the array.

To effect this movement, CCD 18 (88) is mounted in an electromechanical translator 50 of the type illustrated in FIG. 3A. Translator 50 includes a frame 50.1 rigidly mounted within camera 10 and a channel 50.2 in which the CCD 18 is slidably positioned. In a first position, the CCD 18 abuts mechanical stop 50.3 at one end of channel 50.2, and in a second position it abuts mechanical stop 50.5 at the opposite end of channel 50.2. In a third position, CCD 18 (88) is returned to abutment with stop 50.3. Movement or translation of the CCD is brought about by means of suitable well-known piezoelectric actuators (and associated resilient means, such as springs) 50.4 in response to control signals from sensor driver 36 and controller 28 (FIG. 1).

Because a typical pixel size is about 5-10 μm, the translator 50 should be designed to move the CCD 18 (88) in small, steady steps, with rapid damping to reduce any vibration. Piezoelectric actuators and translators with 2-6 μm displacement and 100 kHz resonance frequency are commercially available. [See, for example, the internet website at URL http://www.pi.ws of Physik Instrumente, Auburn, Mass. and Karlsruhe/Palmbach, Germany.]

Our invention may be used with either an electronic shutter (e.g., a focal-plane shutter, which flushes and resets the CCD to create separate exposures) or a mechanical shutter (e.g., two moveable curtains acting in unison to form a slit to achieve short exposure times), or both. In any case, the actuators 50.4 should be able to shift the position of the CCD sufficiently rapidly that two or more consecutive exposures of the CCD take place before there is any significant movement of the object or the camera. (Illustratively, the actuator is capable of shifting the CCD at speeds on the order of 10 mm/s.) As discussed below, an increase in apparent spatial resolution is achieved by multiple exposures and readouts of the image at different locations of the sensor.

Before discussing the operation of various embodiments of our invention, we first define the term exposure. As is well known in the art, an exposure of CCD 18 (88) involves the concurrence of two events: an optical event in which light emanating from object 12 falls upon CCD 18 (88), the incident light generating image data (e.g., charge carriers in the form of electrons) to be collected; and an electrical event in which timing signals applied to CCD 18 (88) place light sensors 18.1p (88.1p) in a charge collecting state. During the optical event, the shutter 14 is open and the lens system 16 focuses light from object 12 onto CCD 18 (88). On the other hand, during the electrical event, timing signals from timer 34 create potential wells within each photosensitive region 18.1p (88.1p). The collected charge remains trapped in the potential wells of the photosensitive regions 18.1p (88.1p) until the photosensitive regions are subsequently placed in a charge transfer state; that is, subsequent timing signals from timer 34 transfer the trapped charge to readout regions 18.1r (88.1r).

In accordance with our invention, during the interval between the time that shutter 14 is opened and the next time it is closed, multiple exposures occur. Thus, with light being continually incident on imaging device 18 (88) while shutter 14 is open, timing signals from timer 34 cycle the photosensitive regions between their charge collecting states and their charge transfer states. The length of each exposure corresponds to the time that the photosensitive regions remain in their charge collecting states during each cycle. For example, we refer to a first exposure, which occurs between a first timing signal that places the photosensitive regions in their charge collecting states and a second timing signal that transfers the collected charge to the first readout regions; and we refer to a second exposure, which occurs between a third timing signal that places the photosensitive regions in their charge collecting states and a fourth timing signal that transfers the collected charge to the second readout regions. In a similar fashion, an n^{th} exposure can be defined.

In operation, when the shutter button is actuated, controller 28 sends a control signal to shutter driver 40, which in turn opens shutter 14, and timer 34 sends timing signals to CCD 18 (88) to place the photosensitive regions 18.1p (88.1p) in their charge collecting states. At this point, which corresponds to the first exposure, the CCD 18 is in a first position as shown in FIG. 3A and the top of FIG. 2B. In the first position each photosensitive region 18.1p of each pixel 18.1 is exposed to light from object 12, which causes charge to fill the potential wells of regions 18.1p, which act as capacitors. After the first exposure, timer 34 sends additional timing signals to CCD 18 (88), so that the charge stored in each of these photosensitive regions 18.1p (88.1p) is transferred to a first subset of readout regions 18.1r (88.1r), which also function as capacitors. For example, in the embodiment of FIG. 2A charge stored in each photosensitive region 18.1p is transferred to its upper readout region 18.1r₁. Thus, the photosensitive regions 18.1p are cleared of charge and are ready to receive light (and store charge) from a subsequent exposure. In contrast, in the embodiment of FIG. 6, after the first exposure charge from each photosensitive region 88.1p is transferred, for example, to its left hand readout region 88.1r₁. Thus, the photosensitive regions 88.1p are cleared of charge.

With the shutter 14 still open, the entire CCD 18 (88) is shifted to a new location; that is, the controller 28 sends a control signal to sensor driver 36, which in turn causes actuator 50 to translate CCD 18 (88) by an amount Δ in a direction perpendicular to the columns of the CCD, as shown in FIGS. 2B and 3A. During the CCD-shifting operation, CCD 18 is still being exposed to light from object 12. However, timer 34 sends further timing signals to CCD 18 (88) to reset or flush photosensitive regions 18.1p (88.1p) of any spurious charge collected during the shifting operation and to return them to their charge collecting states. Now the second exposure begins; charge again fills the potential wells of the photosensitive regions 18.1p (88.1p), but this time the collected charge corresponds to slightly different portions of the object 12. Importantly, light from object 12 that previously fell upon dead space has now fallen upon photosensitive regions. After the second exposure is complete, timer 34 sends additional timing signals to CCD 18 (88), so that the charge is transferred to a second subset of readout regions 18.1r (88.1r), which also function as capacitors. For example, in the embodiment of FIG. 2A charge from each photosensitive region 18.1p is transferred to its lower readout region 18.1r₂. At this stage, readout regions 18.1r₁contain charge from the first exposure, whereas readout regions 18.1r₂ contain charge from the second exposure. Charge from both sets of readout regions for the entire pixel array is subsequently serially outputted to signal processor 20.

In contrast, in the embodiment of FIG. 6, after the second exposure charge from each photosensitive region 88.1p is transferred, for example, to its right hand readout region 88.1r₂. Thus, the photosensitive regions 88.1p are cleared of charge. At this stage, readout regions 88.1r₁, contain charge from the first exposure, whereas readout regions 88.1r₂ contain charge from the second exposure. Charge from both sets of readout regions for the entire pixel array is subsequently outputted in parallel to signal processor 20. Illustratively, charge in left hand readout regions 88.1r₁, is shifted down columns 88.2, whereas charge in right hand readout regions 88.1r₂ is shifted down columns 88.3.

The net effect of shifting the light sensor 18 (88) between multiple exposures is to increase the spatial resolution of the camera by increasing the apparent number of pixels from N to 2N. (By spatial resolution we mean the number of distinguishable lines per unit length.) Thus, using the illustration of FIG. 2, the sensor 18 has only N=8 pixels (FIG. 2B) but has the resolution of a sensor 18′ having 2N=16pixels (FIG. 2C). Similar comments apply to the light sensor of FIG. 6.

In general, the effective spatial resolution is increased from N to nN provided that the camera is designed to have n readout regions per photosensitive region and to provide n multiple exposures each time the shutter is opened. In addition, within each pixel the fraction of the surface area considered dead space is preferably not less than about (n−1)/n of the total surface area of the pixel.

Translation of the Sensor Relative to the Focal Point

Relative translation between the sensor 18 (88) and the focal point can also be achieved by manipulating the lens system 16. In this case, the sensor 18 (88) is stationary, and one or more of the components of the imaging lens subsystem is moved (e.g., translated, rotated, or both), leading to a shift of the image of object 12 between the multiple exposures.

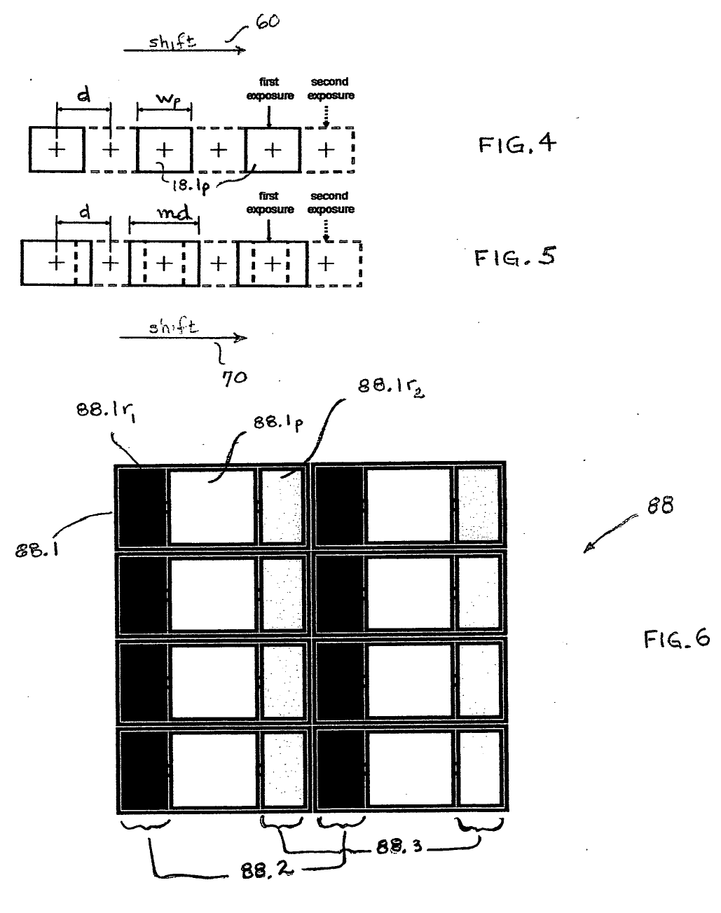

In addition, as mentioned above, the relative shift of sensor 18 (88) can be performed obliquely with respect to the CCD columns (e.g., along a diagonal), which effectively changes the kind of overlap that occurs between photosensitive regions before and after they are shifted. For example, in the light sensor embodiment of FIG. 2B, which illustratively has the pixels arranged in vertical columns and horizontal rows, there will be such an overlap if the horizontal component of the shift Δis less than the width wₚ=md of the photosensitive regions (as in FIG. 5), and there will be no such overlap if the component of the shift Δis equal to this width (as in FIG. 4). In addition, if the shift has both a horizontal component and a vertical component (i.e., an oblique shift), then the vertical component affects which photosensitive regions overlap. Thus, an oblique shift could lead to second-exposure (shifted) photosensitive regions each overlapping four first-exposure photosensitive regions (not shown) rather than two depicted in FIG. 5.

In either case, well-known post signal processing software can then be used to interpolate between the two readings of the overlapping regions to give effective higher resolution than that of the actual, unshifted pixel array. Consider an embodiment in which the light sensor 18 comprises a regular array of rows and columns of pixels (e.g., FIG. 2B) having a pitch 2d defined by the midline-to-midline separation of its photosensitive regions in a direction perpendicular to the columns (FIG. 4). In a straightforward implementation of our invention, the width wₚ of the photosensitive regions 18.1p would be made equal to one half the pitch 2d between those regions, and the pixels would be shifted by a distance d after the first exposure, as depicted in FIG. 4. The position of the pixels during the first exposure is shown by solid lines; during the second exposure by dotted lines. After the first exposure, the sensor is shifted to the right in the direction of arrow 60, and then a second exposure occurs. Therefore, the image data measured in the second exposure in effect creates a contiguous sequence of pixels with no gaps or overlap.

In another embodiment, the sensor array is designed so that the area of each photosensitive region is larger, say m times the half pitch, as depicted in FIG. 5 where the direction of pixel shift is shown by arrow 70. In this case the two exposures overlap spatially, creating a blurring or smoothing effect. As long as m is not too close to two, however, the blurring can be removed with simple signal processing, obtaining the desired half pitch resolution. More specifically, suppose that the ideal sequence of pixel values obtained in the case m=1 is x[1], x[2], x[3], . . . . Then if 1<m<2, the blurred sequence obtained would be y[1], y[2], y[3], . . . where y[i] is given by equation (1):
y[i]=x[i]+ρ(x[i −1]+x [i+1 ]) (1)
where ρ=(m−1)/2. The ideal sequence can be recovered by convolving the data y with an inverse filter to obtain x=h*y. The coefficients h[i] needed for the inverse filter, which would included within image processor 24, are given by equation (2):

$$h [ i ] = {( - 1 )}^{i} {\sum }_{k = \vert i \vert}^{∞} {ρ}^{2 k - \vert i \vert} ( \begin{matrix}2 k - \vert i \vert \\ k\end{matrix} ) . \qquad ( 2 )$$

As long as ρ is not too close to 1/2, the coefficients h[i] diminish rapidly as |i| increases, so that the sequence can be truncated to a small number of coefficients. An alternative implementation is to set x₁=y and then perform several Jacobi iterations of the form given by equation (3):
xₙ₊₁[i]=y[i]−ρ(xₙ[i−1]+xₙ[i+1]) (3)
for n=1, 2, . . . . Again, if ρ is not too close to 1/2, this procedure will converge to a good estimate of x after just a few iterations.
Enhanced Effective Spatial Resolution Embodiments: Other Forms of Dead Space

The embodiments of our invention described above are advantageous because of the presence of dead space in the form of light-insensitive or light-shielded readout regions disposed between photosensitive regions. However, the principles of our invention described above may be applied to digital cameras in which the light sensors include other types of dead space, such as: (1) dead space wherein one subset of photosensitive regions has a different sensitivity to the wavelength of light (color sensitivity) than at least one other subset of photosensitive regions; and (2) dead space wherein one subset of photosensitive regions has a different sensitivity to the intensity of light (exposure sensitivity) than at least one other subset of photosensitive regions. In these examples, from the point of view of collecting image data with one subset of photosensitive regions, all other subsets are considered to constitute dead space. Thus, dead space is present even if the readout regions are buried beneath the photosensitive regions.

Regardless of the type of dead space, all of these embodiments of our invention include multiple readout regions coupled to each photosensitive region, multiple exposures, as well as shifting the light sensor relative to the focal point between exposures, as previously described.

Consider, for example, a color filter array of the type described at page 10 of the Kodak CCD Primer, supra. Color filters are used to render different photosensitive regions responsive to different light wavelengths (e.g., to each of the primary colors, red, blue and green). A photosensitive region that is responsive to one wavelength can be considered as dead space with respect to other light wavelengths. Thus, from the point of view of red light, the green and blue photosensitive regions constitute dead space. Likewise, from the standpoint of green light, red and blue photosensitive regions constitute dead space, and so forth. Therefore, our shift and multiple exposure approach can be used to provide a way to fill in the gaps, thereby attaining higher spatial resolution. Consider, for example, the following portion of an array of photosensitive regions, which are repeated periodically and are labeled R, G or B to designate responsivity to red, green or blue light, respectively.

RBRBRBRB
GGGGGGGG
RBRBRBRB
GGGGGGGG

The light sensor would be shifted relative to the focal point of the lens system diagonally in a direction down and to the right. Consequently, the camera would effectively see a fully-sampled array of green data, whereas it would effectively see only a half-sampled array of blue data and a half-sampled array of red data in a pattern of the type shown below for red data:

| | | | | | | | |
|---|---|---|---|---|---|---|---|
| R | | R | | R | | R | |
| | R | | R | | R | | R |
| R | | R | | R | | R | |
| | R | | R | | R | | R |

Alternatively, with an array of photosensitive regions having the following pattern

RGBRGBRGB
RGBRGBRGB
RGBRGBRGB
RGBRGBRGB

our camera would effectively see a fully-sampled array of data for each color by using two horizontal shifts and three exposures, or 2/3-sampled array of data for each color by using one horizontal shifts and two exposures.

On the other hand, consider a light sensor in which the photosensitive regions that have different sensitivity to light intensity (e.g., an array in which one subset of photosensitive regions has relatively high sensitivity and at least one second subset has a relatively lower sensitivity). It is well known in the art that sensitivity is increased in photosensitive regions having larger surface areas. Therefore, the two subsets could correspond to photosensitive regions having different areas. Thus, a light sensor having both types of photosensitive regions can be used to increase spatial resolution because the more sensitive regions provide useful readings from dark areas of object 12, whereas less sensitive regions provide useful readings from bright areas of object 12. The two sets of readings are combined by post-processing techniques well known in the art to obtain a high quality image of a high contrast scene.

Enhanced Effective Dynamic Range Embodiment

Photosensitive regions of the type employed in the CCD and CMOS light sensor embodiments of our invention effectively measure the energy given by the product aIt, where a is the sensitivity of a photosensitive region, I is the intensity of light incident on the photosensitive region, and t is the exposure time. In order to get useful data for generating an image, the energy has to fall between upper and lower bounds, which in turn define the dynamic range of the light sensor and hence of the camera. If the object (or the scene including the object) has relatively low contrast, there is not significant variation in the intensity of light falling on different photosensitive regions. Therefore, it is straightforward to find a common exposure time that is suitable for all of the photosensitive regions; that is, suitable in the sense that the energy absorbed by each photosensitive region falls within the dynamic range. On the other hand, if the object or scene has relatively high contrast, there will be significant variation in the intensity of light falling on different photosensitive regions. Therefore, there may be no common exposure time that is suitable for all photosensitive regions. Usually a trade off occurs. If the exposure time is too long, some photosensitive regions will be saturated; if it is too short, others will lose data in the noise floor.

However, another embodiment of our invention increases the effective dynamic range of such light sensors, thereby making it more suitable for use in high contrast objects or scenes. In this case, all of the photosensitive regions have essentially the same sensitivity. However, the first and second exposures have different time durations. More specifically, if the object 12 constitutes, for example, a high contrast scene, the first exposure has a relatively short duration (e.g., about 0.5 to 5 ms) that generates in the photosensitive regions charge, which is subsequently transferred to and stored in a first subset of readout regions. On the other hand, the second exposure has a relatively longer duration (e.g., about 10 to 100 ms) that generates in the photosensitive regions charge, which is subsequently transferred to and stored in a second subset of readout regions. Then, the stored charge of both subsets is read out and processed.

This embodiment of our invention includes multiple readout regions coupled to each photosensitive region and multiple exposures, as previously described, but obviates the need to shift the light sensor relative to the focal point between exposures.

For example, consider an array of sixteen photosensitive regions with essentially no dead space, as shown in FIG. 2C, and with the readout regions buried underneath the photosensitive regions. For an object or scene that has relatively high contrast, the camera would first take a short exposure image and store sixteen data points in a first subset of readout regions, and then would take a relatively longer exposure image and store sixteen additional data points in a second, different subset of readout regions. (Of course, the order of the exposures can be reversed.) The stored data correspond to the same sixteen spatial locations of the object or scene. The data points for bright areas of the object or scene are useful data stored in the first subset of readout regions but are saturated in the second subset of readout regions. Conversely, the data points for dark areas of the object or scene are useful data stored in the second subset of readout regions but are very small (essentially zero) in the first subset of readout regions. Then, well known signal processing techniques are utilized to combine the data stored in both subsets of the readout regions to obtain sixteen useful data points.

Other Embodiments

It is to be understood that the above-described arrangements are merely illustrative of the many possible specific embodiments that can be devised to represent application of the principles of the invention. Numerous and varied other arrangements can be devised in accordance with these principles by those skilled in the art without departing from the spirit and scope of the invention.

In particular, another embodiment of our invention combines several of the above approaches. For example, if the light sensor has dead space, comprising an array of photosensitive regions all having essentially the same sensitivity and three readout regions per photosensitive region, then the controller can be designed for three exposures per cycle: first and second short exposures (with the CCD translated in between these exposures) and a third longer exposure (with no translation of the CCD between the second and third exposures). This embodiment would provide enhanced resolution for bright areas of object 12 and normal resolution for dark areas.

We also note that the final image created by our camera may be blurred if the image itself is changing faster than the duration of the multiple exposures. In that case, our camera may be provided with a mechanism of the kind described by in the prior art to move the light sensor 18 during exposure in response to any external vibration. This design, which allows a photographer to take sharp photographs under low light conditions without the use of a tripod, can also be used for multiple exposures to increase the resolution of existing sensors. [See, for example, US Published Patent Applications 2003/0210343 and 2004/0240867, both of which are incorporated herein by reference.]

In addition, our invention has the advantage of reducing image smear during readout at the price of increasing complexity somewhat. Although the use of an IL-type CCD architecture in some embodiments decreases the fraction of photosensitive area in comparison to a full frame sensor, lower sensitivity can be compensated by means of a well-known microlens array, which concentrates and redirects light to the photosensitive area, as described in the Kodak CCD Primer, supra.

Moreover, although we have depicted light sensor 18 as a rectangular array of rectangular pixels arranged in columns and rows, those skilled in the art will appreciate that our invention can be implemented with other types of arrays in which the pixels are arranged in configurations other than rows/columns and/or the pixels have shapes other than rectangular, albeit probably at the expense of increased complexity.

We note that generally an image may contain multiple data planes, where a data plane is a two-dimensional (2D) array of numbers corresponding to measurements of a particular type (e.g., measurements based on the color or intensity of the incident light, or based on exposure time). The position of a number in the array corresponds to a spatial location on the object or image where the measurement was taken. For example, in the enhanced spatial resolution embodiment of our invention in which different photosensitive regions have different responsivity to color, a black and white photo consists of one data plane, whereas a color photo has three data planes, i.e. three 2D arrays of numbers, corresponding to RGB. On the other hand, in the enhanced spatial resolution embodiment of our invention in which different photosensitive regions have different responsivity to light intensity, there are two data planes: an array of numbers measured with high sensitivity and an array measured with low sensitivity regions. Subsequent processing inside or outside the camera combines the multiple data planes to form a single black & white or color photo. In both of these cases, our invention may be utilized to increase the spatial resolution of each of the data planes in an object or image, thereby increasing the spatial resolution of the overall image. Finally, in the enhanced dynamic range embodiment of our invention, there are two data planes: an array of numbers measured with short exposure and an array measure with longer exposure. Subsequent processing inside or outside the camera combines the multiple data planes into a single photo.

We Claim:

1 . Apparatus for storing an optical image of an object, said apparatus comprising:
an imaging device having a multiplicity of pixels,
each pixel including a light sensor and a multiplicity of storage cells coupled to said sensor,
within each pixel a first one of its storage cells being configured to store data corresponding to a first exposure of its sensor and a second one of its storage cells being configured to store data corresponding to a second exposure of its sensor.

2. The apparatus of claim 1, further comprising:
a lens system for focusing light from said object onto said imaging device, and
a translator configured to produce a relative translation between said imaging device and the focal point of said lens system, said translation occurring between said first and second exposures.

3. The apparatus of claim 2, wherein said multiplicity of pixels forms an array of pixels disposed in columns and rows having a uniform pitch between columns, and said translator is configured to produce said translation in an amount that is approximately one half said pitch in a direction essentially perpendicular to said columns.

4. The apparatus of claim 1, wherein each of said light sensors has multiple sides and at least two of its storage cells are located on the same side of said light sensor.

5. The apparatus of claim 1, wherein each of said light sensors has multiple sides and at least one of its storage cells is located on one side of said light sensor and at least a different one of its storage cells is located on a different side of said light sensor.

6. The apparatus of claim 2, further comprising a light shutter having an open state in which light from said object illuminates selected ones of said sensors and a closed state in which light from said object illuminates none of said sensors and a controller configured to (i) open said shutter, thereby to expose said sensors to light from said object and to generate in said sensors electronic data representing said image; (ii) transfer said data from said sensors to said first storage cells; (iii) actuate said translator to shift said sensors relative to said focal point, thereby to expose said shifted sensors to light from said image and to generate in said sensors additional data representing said object; (iv) remove any spurious data from said sensors generated therein during the shifting operation and prior to the generation of said additional data; (v) transfer said additional data from said sensors to said second storage cells; and (vi) close said shutter.

7. The apparatus of claim 1, wherein a first subset of said light sensors has a first exposure sensitivity to light from said object and second subset of said light sensors has a second exposure sensitivity to light from said object.

8. The apparatus of claim 1, wherein all of said sensors have essentially the same sensitivity to the intensity of light from said object and wherein said first and second exposures have different durations.

9. The apparatus of claim 1, wherein a first subset of said pixels has a first frequency sensitivity to light of a first primary color, a second subset of said pixels has a second frequency sensitivity to light of a second primary color, and a third subset of said pixels has a third frequency sensitivity to light of a third primary color.

10. The apparatus of claim 1, wherein said pixels include dead space, each of said pixels comprises n said storage cells, and within each of said pixels the surface area occupied by said dead space is not less than about (n−1)/n of the total surface area of said pixel.

11. A method of generating electronic data representing an optical image of an object comprising the steps of:
(a) making light emanating from the object incident upon the pixels of an optical imaging device;
(b) providing multiple exposures of the pixels during step (a), each exposure generating electronic image data within the pixels; and
(c) after each exposure transferring the data into a subset of readout devices, a different subset being receiving data during consecutive transfer operations.

12. The method of claim 11, further including the step of translating the pixels between each exposure operation.

13. The method of claim 12, wherein said imaging device comprises an array of pixels arranged in columns and rows, and the pixels are translated by a distance of about one half the pitch of the pixels in a direction essentially perpendicular to the columns.

14. The method of claim 12, further including the step of removing an electronic data generated in the pixels during the translating step.

15. The method of claim 11, wherein the multiple exposures include at least two exposures of different duration.

16. A method of generating electronic data representing an optical image of an object comprising the steps of:
(a) focusing light emanating from the object to a focal point onto pixels of an optical imaging device; the light generating in the device electronic first data corresponding to the image;
(b) removing the first data from the exposed pixels;
(c) storing the removed first data in first subset of storage cells;
(d) focusing light emanating from the object to a focal point on the same pixels; the light generating electronic second data corresponding to the essentially same image;
(e) removing the second data from the exposed same pixels;
(f) storing the removed second data in a second subset of storage cells; then
(g) reading out the stored first and second data.

17. The method of claim 16, further comprising the steps of:
(h) opening a shutter to expose the pixels to light from the object during at least steps (a) and (d);
(i) between steps (a) and (d), producing a relative lateral translation between the pixels and the focal point; and
(j) removing any electronic third data generated in the device during step (i).

18. The method of claim 17, wherein the pixels form an array comprising columns and rows of pixels having a uniform pitch between columns, and step (i) produces a lateral translation in an amount that is approximately one half the pitch in a direction essentially perpendicular to the columns.

19. The method of claim 16, wherein the duration of steps (a) is different from the duration of step (d).
